(19) United States
(12) Patent Application Publication
(10) Pub. No.: US 2025/0057015 A1
(43) Pub. Date: Feb. 13, 2025

(54) DISPLAY PANEL

(71) Applicants: HEFEI VISIONOX TECHNOLOGY CO., LTD., Hefei (CN); KUNSHAN GO-VISIONOX OPTO-ELECTRONICS CO., LTD, Kunshan (CN)

(72) Inventors: Xuejing ZHU, Hefei (CN); Xiaoxi SUN, Hefei (CN); Bing HAN, Hefei (CN)

(21) Appl. No.: 18/792,491

(22) Filed: Aug. 1, 2024

(30) Foreign Application Priority Data
Aug. 10, 2023 (CN) 202311017132.0
May 21, 2024 (CN) 202410646170.0

(51) Int. Cl. H10K 59/80; H10K 59/122

(52) U.S. Cl. CPC H10K 59/8731; H10K 59/122

(57) ABSTRACT

The present application discloses a display panel. The display panel comprises a display region, a hole region, and a transition region located between the display region and the hole region. The display panel further comprises a substrate; a pixel defining layer located on a side of the substrate, the pixel defining layer comprising at least one pixel defining portion and a pixel opening enclosed by the pixel defining portion; a light-emitting layer comprising at least one light-emitting unit located within the pixel opening; and an inorganic encapsulation layer located on a side of the light-emitting unit facing away from the substrate. The inorganic encapsulation layer comprises a first hole configured to avoid cutting damage. The hole region is

### CROSS-REFERENCES TO RELATED APPLICATIONS

This application claims priority to Chinese Patent Application No. 202311017132.0 filed on Aug. 10, 2023, entitled “DISPLAY PANEL, DISPLAY APPARATUS, AND METHOD FOR MANUFACTURING DISPLAY PANEL” and Chinese Patent Application No. 202410646170.0 filed on May 21, 2024, entitled “DISPLAY PANEL, DISPLAY APPARATUS, AND METHOD FOR MANUFACTURING DISPLAY PANEL”, which are hereby incorporated by reference in their entireties.

### FIELD

The present application relates to the field of display, and in particular, to a display panel.

### BACKGROUND

Flat panel display devices based on technologies such as Organic Light Emitting Diode (OLED) and Light Emitting Diode (LED) have advantages of high quality, power saving, thin body and wide application range, and are widely used in mobile phones, TVs, laptops, desktop computers and other consumer electronic products, which thus become the mainstream of the display devices.

However, it is necessary to improve usage performance of the current OLED display products.

### SUMMARY

Embodiments of the present application provide a display panel, a display apparatus, and a method for manufacturing a display panel, which are intended to improve the performance of OLED display products.

In a first aspect of the present application, an embodiment provides a display panel comprising a display region, a hole region, and a transition region located between the display region and the hole region. The display panel further comprises: a substrate; a pixel defining layer located on a side of the substrate, the pixel defining layer comprising at least one pixel defining portion and a pixel opening enclosed by the pixel defining portion; a light-emitting layer comprising at least one light-emitting unit located within the pixel opening; and an inorganic encapsulation layer located on a side of the light-emitting unit facing away from the substrate. The inorganic encapsulation layer comprises a first hole configured to avoid cutting damage. The hole region is within the first hole.

In a second aspect of the present application, an embodiment provides a display panel comprising a display region, a hole region, and a transition region located between the display region and the hole region. The display panel further comprises: a substrate; a pixel defining layer located on a side of the substrate, the pixel defining layer comprising at least one pixel defining portion and a pixel opening enclosed by the pixel defining portion; a light-emitting layer comprising at least one light-emitting unit located within the pixel opening; and an inorganic encapsulation layer located on a side of the light-emitting unit facing away from the substrate. The inorganic encapsulation layer comprises a blocking trench located in the transition region.

In a third aspect of the present application, an embodiment provides a display panel comprising a display region, a hole region, and a transition region located between the display region and the hole region. The display panel further comprises: a substrate; a first insulating layer located on the substrate, the first insulating layer being provided with a first hollow portion, the first hollow portion being located in the transition region and spaced apart from the display region, and the first hollow portion extending from the transition region to an interface between the hole region and the transition region; a pixel defining layer located on a side of the first insulating layer facing away from the substrate and comprising a pixel defining portion and a pixel opening enclosed by the pixel defining portion; and a light-emitting layer comprising at least one light-emitting unit located within the pixel opening.

According to the display panel in the embodiments of the present application, the display panel includes a display region, a transition region, and a hole region, the display region is arranged around the transition region, and the transition region is arranged around the hole region. The display region is configured to realize light-emitting display of the display panel, and the hole region is configured to arrange a photosensitive assembly. The display panel further includes a substrate, a first insulating layer, and a pixel defining layer. The pixel defining layer includes a pixel defining portion, and a pixel opening enclosed by the pixel defining portion. The pixel opening is configured to arrange a light-emitting unit to realize light-emitting display of the display panel. The first insulating layer located between the pixel defining layer and the substrate is provided with a first hollow portion. The first hollow portion is located in the transition region and spaced apart from the display region, so that a brittle film layer of the display panel at the first hollow portion is thinned or removed, and when the substrate is cut at the first hollow portion, it is difficult for the first insulating layer to form cracks and the cracks are difficult to extend to the display region, thereby improving use performance of an OLED display panel.

### BRIEF DESCRIPTION OF THE DRAWINGS

FIG. 1 is a schematic top view of a display panel according to an embodiment of the present application;

FIG. 2 is a sectional view at A-A in FIG. 1;

FIG. 3 is a sectional view at A-A in FIG. 1 according to another embodiment;

FIG. 4 is a sectional view at A-A in FIG. 1 according to yet another embodiment;

FIG. 5 is a partial enlarged view of FIG. 4;

FIG. 6 is a sectional view at A-A in FIG. 1 according to still another embodiment;

FIG. 7 is a sectional view at A-A in FIG. 1 before cutting according to another embodiment;

FIG. 8 is a sectional view at A-A in FIG. 1 before cutting according to yet another embodiment;

FIG. 9 is a schematic flowchart of a method for manufacturing a display panel according to an embodiment of the present application;

FIG. 10 is a partial top view of a display panel according to an embodiment of the present application;

FIG. 11 is a sectional view at A-A in FIG. 1 according to still another embodiment;

FIG. 12 is a sectional view at A-A in FIG. 1 according to still another embodiment;

FIG. 13 is a sectional view at A-A in FIG. 1 according to still another embodiment;

FIG. 14 is a sectional view at A-A in FIG. 1 according to still another embodiment;

FIG. 15 is a partial sectional view of a display region of a display panel according to an embodiment of the present application;

FIG. 16 is a schematic flowchart of a method for manufacturing a display panel according to an embodiment of the present application;

### DESCRIPTION OF REFERENCE NUMERALS

10: display panel; 11: display region; 12: transition region; 13: hole region;
100: substrate; 110: base; 120: protective film; 121: fourth recess;
200: first insulating layer; 210: first hollow portion; 211: first opening; 212: second opening; 220: third hollow portion;
300: pixel defining layer; 310: pixel defining portion; 311: first pixel defining portion; 312: second pixel defining portion; 313: extension portion; 320: pixel opening; 321: first pixel opening;
400: barrier wall;
500: isolation structure; 501: first layer; 502: second layer; 510: first isolation portion; 511: first isolation opening; 520: second isolation portion;
600: light-emitting layer; 610: first light-emitting unit; 620: second light-emitting unit;
700: first electrode layer; 710: first electrode; 720: second electrode;
810: first encapsulation layer; 811: first section; 812: second section; 813: first thinned portion; 820: second encapsulation layer; 830: third encapsulation layer; 831: third section; 832: fourth section; 833: second hollow portion or first hole for avoiding cutting damage; 834: second thinned portion; 840: blocking trench.

### DETAILED DESCRIPTION

Embodiments of the present application provide a display panel, a display apparatus, and a method for manufacturing a display panel. Various embodiments of the display panel, the display apparatus, and the method for manufacturing the display panel will be described below with reference to the accompanying drawings.

An embodiment of the present application provides a display panel. The display panel is an OLED (Organic Light Emitting Diode, OLED) display panel.

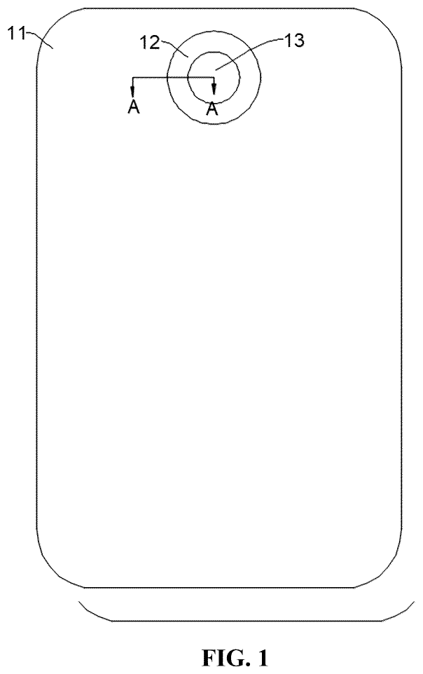

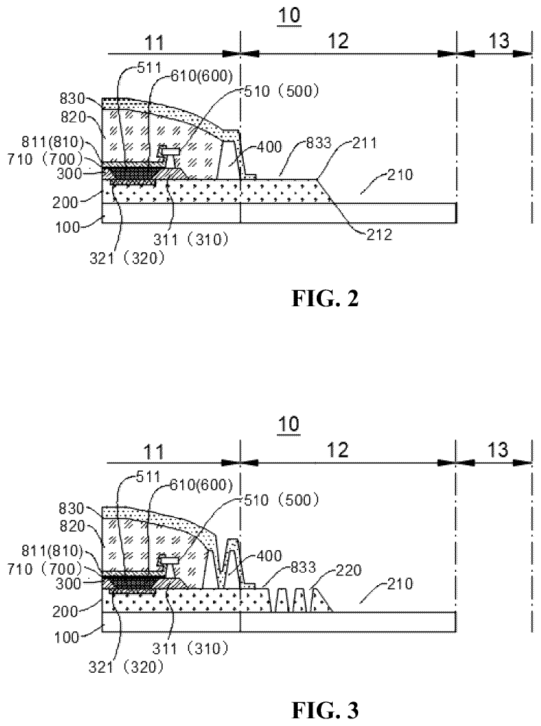

Referring to FIG. 1 and FIG. 2 together, FIG. 1 is a schematic top view of a display panel according to an embodiment of the present application; and FIG. 2 is a sectional view at A-A in FIG. 1.

As shown in FIG. 1 and FIG. 2, in a first aspect of the present application, an embodiment provides a display panel 10. The display panel 10 includes a display region 11, a transition region 12, and a hole region 13. The display region 11 is arranged around the transition region 12. The transition region 12 is arranged around the hole region 13. The display panel 10 further includes: a substrate 100, a first insulating layer 200, and a pixel defining layer 300. The first insulating layer 200 is located on the substrate 100. The first insulating layer 200 is provided with a first hollow portion 210. The first hollow portion 210 is located in the transition region 12 and spaced apart from the display region 11. The first hollow portion 210 extends from the transition region 12 to an interface between the hole region 13 and the transition region 12. The pixel defining layer 300 is located on a side of the first insulating layer 200 facing away from the substrate 100. The pixel defining layer 300 includes a pixel defining portion 310 and a pixel opening 320 enclosed by the pixel defining portion 310.

Optionally, the interface is a cutting edge of the hole region 13 in the display panel 10, and the display panel 10 is cut at the interface to form the hole region 13.

According to the display panel 10 in the embodiments of the present application, the display panel 10 includes a display region 11, a transition region 12, and a hole region 13, the display region 11 is arranged around the transition region 12, and the transition region 12 is arranged around the hole region 13. The display region 11 is configured to realize light-emitting display of the display panel 10, and a photosensitive assembly is arranged in the hole region 13 under the display panel. The display panel 10 further includes a substrate 100, a first insulating layer 200, and a pixel defining layer 300. The pixel defining layer 300 includes a pixel defining portion 310, and a pixel opening 320 enclosed by the pixel defining portion 310. The pixel opening 320 is configured to arrange a light-emitting unit. The first insulating layer 200 located between the pixel defining layer 300 and the substrate 100 is provided with a first hollow portion 210. The first hollow portion 210 is located in the transition region 12 and spaced apart from the display region 11, so that a brittle film layer of the display panel 10 at the first hollow portion 210 is thinned or removed, and when the substrate 100 is cut at the first hollow portion 210, it is difficult for the first insulating layer 200 to form cracks and the cracks are difficult to extend to the display region 11, thereby improving the performance of the OLED display panel 10.

Optionally, the display panel 10 includes an array layer, and the first insulating layer 200 includes an interlayer insulating layer located within the array layer. For example, the array layer includes a metal layer, the metal layer includes a first metal layer, a second metal layer, and a third metal layer arranged in stack, and the first insulating layer 200 includes an interlayer insulating layer between adjacent metal layers. For example, the array layer includes an active layer and a gate layer, and the first insulating layer 200 includes an inter-gate insulating layer between the active layer and the gate layer.

Optionally, the first insulating layer 200 includes a planarization layer located on a side of the pixel defining layer 300 facing the substrate 100.

In some optional embodiments, the pixel defining portion 310 includes a first pixel defining portion 311 located in the display region 11, and the pixel opening 320 includes a first pixel opening 321 enclosed by the first pixel defining portion 311. The display panel 10 further includes a barrier wall 400, the barrier wall 400 is located on a side of the first insulating layer 200 facing away from the substrate 100, and the barrier wall 400 is arranged between the first pixel defining portion 311 and the first hollow portion 210 and forms an annular shape and surrounds the transition region 12.

In such optional embodiments, the first pixel defining portion 311 is located in the display region 11 to define a light-emitting region of the display region 11. That is, the first pixel opening 321 is enclosed by the first pixel defining portion 311, so that the display panel 10 emits light at the first pixel opening 321. The barrier wall 400 is arranged between the first pixel defining portion 311 and the first hollow portion 210, and the barrier wall 400 allows a portion of a film layer to be arranged in the display region 11 and blocked at the position of the barrier wall 400, which can alleviate the problem of water and oxygen intrusion due to entry of water vapor into the display region 11 from the transition region 12.

Optionally, a plurality of barrier walls 400 are spaced apart. The arrangement of the plurality of barrier walls 400 can further extend a path of water and oxygen intrusion and alleviate the problem of water and oxygen intrusion due to entry of water vapor into the display region 11 from the transition region 12.

In some optional embodiments, the display panel 10 further includes an isolation structure 500 and a light-emitting layer 600. The isolation structure 500 is located on a side of the pixel defining portion 310 facing away from the substrate 100. The isolation structure 500 includes a first isolation portion 510 located on a side of the barrier wall 400 facing away from the transition region 12. A first isolation opening 511 is enclosed by the first isolation portion 510. The first pixel opening 321 is located in the first isolation opening 511. The light-emitting layer 600 is located on the side of the pixel defining portion 310 facing away from the substrate 100. The light-emitting layer 600 includes a first light-emitting unit 610 located in the first isolation opening 511.

In such optional embodiments, the first isolation portion 510 is arranged in the display region 11 and a plurality of first isolation openings 511 are enclosed by the first isolation portion 510 so as to partition the light-emitting layer 600 to form a plurality of first light-emitting units 610 disconnected from each other, thereby reducing crosstalk of carriers in the light-emitting layer 600 and improving display effect of the display panel 10. Moreover, the first light-emitting unit 610 may be manufactured without a precision mask, which can reduce development and use of the precision mask so as to reduce manufacturing costs.

Optionally, a portion of the light-emitting layer 600 may be etched to form a hollow in the transition region 12 to further reduce the film layer thickness of the display panel 10 in the transition region 12 so as to reduce difficulty of cutting.

As shown in FIG. 2, in some optional embodiments, the display panel 10 further includes a first electrode layer 700. The first electrode layer 700 is located on a side of the light-emitting layer 600 facing away from the substrate 100. The first electrode layer 700 includes a first electrode 710 located in the first isolation opening 511.

In such optional embodiments, the first electrode layer 700 is partitioned by the first isolation portion 510 to form first electrodes 710 spaced apart from each other. Each of the first electrodes 710 is located in the first isolation opening 511. The first electrodes 710 spaced apart from each other are electrically connected through the first isolation portion 510 to form an entire-surface electrode.

Optionally, the first electrode layer 700 maybe partially be etched in the transition region 12 to further reduce the film layer thickness of the display panel 10 in the transition region 12 so as to reduce the difficulty of cutting.

In some optional embodiments, the display panel 10 further includes a first encapsulation layer 810. The first encapsulation layer 810 is located on a side of the first electrode layer 700 facing away from the substrate 100. The first encapsulation layer 810 includes a first section 811 located in the display region 11.

In such optional embodiments, the first encapsulation layer 810 encapsulates the first electrode layer 700 and the light-emitting layer 600 to reduce erosion of water and oxygen on the first electrode layer 700 and the light-emitting layer 600. The first section 811 of the first encapsulation layer 810 is located in the display region 11, which improves encapsulation performance of the display panel 10 in the display region 11.

Optionally, a portion of the first encapsulation layer 810 in the transition region 12 may be etched to further reduce the film layer thickness of the display panel 10 in the transition region 12 and reduce the difficulty of cutting.

In some optional embodiments, the display panel 10 further includes a second encapsulation layer 820. The second encapsulation layer 820 is located on a side of the first encapsulation layer 810 facing away from the substrate 100 and located on a side of the barrier wall 400 facing away from the transition region 12.

In such optional embodiments, the first encapsulation layer 810 and the second encapsulation layer 820 are used in the display panel 10 for multi-layer encapsulation, which further improves the encapsulation performance of the display panel 10. The second encapsulation layer 820 is blocked at the barrier wall 400 so that each second encapsulation layer 820 is located in the display region 11, which can alleviate the problem of water and oxygen intrusion due to entry of water vapor into the display region 11 from the transition region 12.

In some optional embodiments, the display panel 10 further includes a third encapsulation layer 830. The third encapsulation layer 830 is located on a side of the second encapsulation layer 820 facing away from the substrate 100. The third encapsulation layer 830 includes a second hollow portion 833 located in the transition region 12, or the third encapsulation layer 830 is located in the display region 11 and the transition region 12.

In such optional embodiments, the first encapsulation layer 810, the second encapsulation layer 820, and the third encapsulation layer 830 are used in the display panel 10 for multi-layer encapsulation, which further improves the encapsulation performance of the display panel 10. The third encapsulation layer 830 is provided with the second hollow portion 833 in the transition region 12, so that a brittle film layer of the display panel 10 is thinned at the second hollow portion 833 of the transition region 12, and when the substrate 100 is cut at the second hollow portion 833, it is difficult for the third encapsulation layer 830 to form cracks and the cracks are difficult to extend to the display region 11.

Optionally, the first encapsulation layer 810 includes an inorganic material. The first encapsulation layer 810 is encapsulated using the inorganic material. The first encapsulation layer 810 made of the inorganic material is denser and has better encapsulation performance.

Optionally, the second encapsulation layer 820 includes an organic material. The second encapsulation layer 820 is encapsulated using the organic material, which further improves encapsulation performance of the encapsulation layer.

Optionally, the third encapsulation layer 830 includes an inorganic material. The first encapsulation layer 810, the second encapsulation layer 820, and the third encapsulation layer 830 are encapsulated by using the inorganic material, the organic material, and the inorganic material respectively, to form a thin film encapsulation (Thin Film Encapsulation, TFE) structure, which further improves encapsulation performance of the encapsulation layers.

In some optional embodiments, the first section 811 is located on a side of the first isolation portion 510 away from the transition region 12, the first isolation portion 510 is close to an edge of the transition region 12.

In such optional embodiments, the first encapsulation layer 810 is partitioned by the first isolation portion 510, so that the first encapsulation layer 810 cannot continuously extend to the transition region 12, which further reduces the film layer thickness of the display panel 10 in the transition region 12 and reduces the difficulty of cutting. Moreover, when the substrate 100 is cut in the transition region 12, it is difficult for the first encapsulation layer 810 to form cracks and the cracks are difficult to extend to the display region 11.

In some optional embodiments, the third encapsulation layer 830 includes a second hollow portion 833 located in the transition region 12, and an orthographic projection of the first hollow portion 210 on the substrate 100 is at least partially overlapped with an orthographic projection of the second hollow portion 833 on the substrate 100.

In such optional embodiments, the orthographic projections of the first hollow portion 210 and the second hollow portion 833 on the substrate 100 are at least partially overlapped with each other, so that the first hollow portion 210 and the second hollow portion 833 are at least partially in communication. At an overlapping position, the display panel 10 has a smaller thickness, making it easier to cut the display panel 10 at the overlapping position. Moreover, it is difficult for the third encapsulation layer 830 and the first insulating layer 200 to form cracks and the cracks are difficult to extend to the display region 11.

In some optional embodiments, the orthographic projection of the first hollow portion 210 on the substrate 100 is located within the orthographic projection of the second hollow portion 833 on the substrate 100.

In such optional embodiments, an orthographic projection area of the second hollow portion 833 is larger than that of the first hollow portion 210, so that when the substrate 100 is cut in the first hollow portion 210, the thickness is lower and the difficulty of cutting is low. Moreover, since the second hollow portion 833 has a larger area, it is more difficult for the third encapsulation layer 830 to form cracks and extend to the display region 11.

In some optional embodiments, the first hollow portion 210 is arranged running through the first insulating layer 200 along a thickness direction of the display panel 10.

In such optional embodiments, the first hollow portion 210 is arranged running through the first insulating layer 200, which further reduces the thickness of the first insulating layer 200 at the first hollow portion 210 and reduces the difficulty of cutting the substrate 100 at the first hollow portion 210. Moreover, when the substrate 100 is cut at the first hollow portion 210, it is more difficult for the first insulating layer 200 to form cracks and extend to the display region 11, which improves reliability of light emission of the display panel 10.

Referring to FIG. 3, FIG. 3 is a sectional view at A-A in FIG. 1 according to another embodiment.

As shown in FIG. 3, in some optional embodiments, the first insulating layer 200 is provided with a third hollow portion 220 located in the transition region 12, and the third hollow portion 220 is arranged around the first hollow portion 210 and spaced apart from the first hollow portion 210.

In such optional embodiments, the third hollow portion 220 is arranged around the first hollow portion 210, so that, when the first insulating layer 200 is provided with another film layer, the arrangement of the third hollow portion 220 can increase a path of water and oxygen intrusion, making it more difficult for water and oxygen to intrude into the display region 11 through the transition region 12 and ensuring reliability of the display panel 10.

Optionally, a plurality of third hollow portions 220 are spaced apart. The arrangement of the plurality of third hollow portions 220 can further increase the path of water and oxygen intrusion.

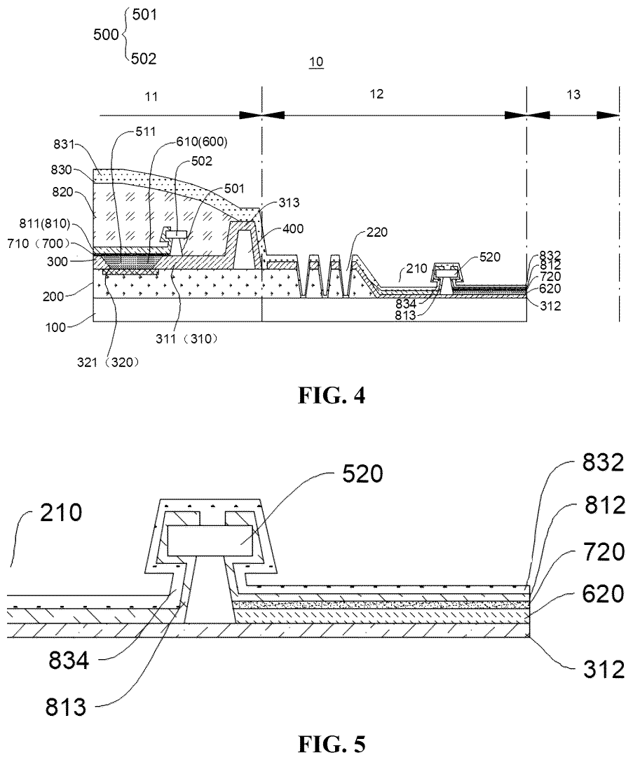

Referring to FIG. 4 and FIG. 5 together, FIG. 4 is a sectional view at A-A in FIG. 1 according to another embodiment; and FIG. 5 is a partial enlarged view of FIG. 4.

As shown in FIG. 4 and FIG. 5, in some optional embodiments, the pixel defining portion 310 includes a second pixel defining portion 312 located in the first hollow portion 210. The isolation structure 500 includes a second isolation portion 520 located on the second pixel defining portion 312, and the second isolation portion 520 is spaced apart from the hole region 13. The light-emitting layer 600 includes a second light-emitting unit 620 located on a side of the second isolation portion 520 facing the hole region 13.

In such optional embodiments, the second pixel defining portion 312 and the second isolation portion 520 are arranged in the first hollow portion 210, and the second light-emitting unit 620 is provided on the side of the second isolation portion 520 facing the hole region 13, so that a film layer structure in the first hollow portion 210 is close to the film structure for cutting in the related art, and the substrate 100 can be cut using an existing cutting device and known device parameters, reducing the difficulty of cutting.

Optionally, the first electrode layer 700 includes a second electrode 720 on the side of the second isolation portion 520 facing the hole region 13, and the second electrode 720 is provided on the side of the second isolation portion 520 facing the hole region 13, so that the film layer structure in the first hollow portion 210 is close to the film structure for cutting in the related art, and the substrate 100 can be cut using an existing cutting device and known device parameters, reducing the difficulty of cutting.

In some optional embodiments, the first encapsulation layer 810 includes a second section 812 located in the transition region 12, and at least part of the second section 812 is located in the first hollow portion 210.

In such optional embodiments, the second section 812 of the first encapsulation layer 810 is arranged in the first hollow portion 210, so that the film layer structure in the first hollow portion 210 is close to the film structure for cutting in the related art, and the substrate 100 can be cut using an existing cutting device and known device parameters, reducing the difficulty of cutting.

In some optional embodiments, the second section 812 includes first thinned portions 813 located on two sides of the second isolation portion 520.

In such optional embodiments, the second section 812 is provided with the first thinned portions 813 on the two sides of the second isolation portion 520, that is, the second section 812 is thinner on the two sides of the second isolation portion 520, so that when the substrate 100 is cut on a side of the second isolation portion 520 facing the hole region 13, generated cracks are easily broken at the first thinned portions 813 and are difficult to continuously extend to the display region 11.

Optionally, the second section 812 and the first section 811 are spaced apart, so that when the substrate 100 is cut at the second section 812 on the first hollow portion 210, cracks generated in the second section 812 cannot extend to the first section 811, which ensures reliability of display of the display panel 10.

Optionally, the third encapsulation layer 830 includes a third section 831 located in the display region 11 and a fourth section 832 located in the transition region 12, and at least part of the fourth section 832 is located in the first hollow portion 210. The fourth section 832 of the third encapsulation layer 830 is arranged in the first hollow portion 210, so that the film layer structure in the first manufacturing trench is close to the film structure for cutting in the related art, and the substrate 100 can be cut using an existing cutting device and known device parameters, reducing the difficulty of cutting.

Optionally, the fourth section 832 includes second thinned portions 834 on the two sides of the second isolation portion 520, that is, the fourth portion 832 is thinner on the two sides of the second isolation portion 520, so that when the substrate 100 is cut on the side of the second isolation portion 520 facing the hole region 13, generated cracks are easily broken at the second thinned portions 834 and are difficult to continuously extend to the display region 11.

As shown in FIG. 4, optionally, the isolation structure 500 includes a first layer 501, and each first electrode 710 is electrically connected to the first layer 501. The first electrodes 710 spaced apart from each other are electrically connected through the first layer 501 to form an entire-surface electrode. The first electrodes 710 and the first layer 501 are more easily overlapped, thereby improving overlap efficiency of the first electrodes 710.

In some optional embodiments, the isolation structure 500 further includes a second layer 502 located on a side of the first layer 501 facing away from the substrate 100, and an orthographic projection of the first layer 501 on the substrate 100 is within an orthographic projection of the second layer 502 on the substrate 100.

In such optional embodiments, the first layer 501 and the second layer 502 are arranged to form the isolation structure 500, the orthographic projection of the first layer 501, which is arranged close to the substrate 100 on the substrate 100, is within the orthographic projection of the second layer 502 on the substrate 100, an area of the second layer 502 is larger than that of the first layer 501, and the second layer 502 covers a surface of the first layer 501 close to the second layer 502. In this case, the first layer 501 is recessed relative to the second layer 502 in a direction away from the pixel opening 320. When the light-emitting layer 600 is manufactured, the light-emitting layer 600 has a large gap at an edge of the isolation structure 500, and the first layer 501 is concave relative to the second layer 502. The light-emitting layer 600 is difficult to connect at the edge of the isolation structure 500, resulting in breakage. The light-emitting layer 600 is broken to form the first light-emitting unit 610 and the second light-emitting unit 620 disconnected from each other. Moreover, the second layer 502 is concave relative to the first layer 501. When the first encapsulation layer 810 and the third encapsulation layer 830 are manufactured, the second section 812 is provided with thinner first thinned portions 813 on two sides of the second layer 502, and the fourth section 832 is provided with thinner second thinned portions 834 on the two sides of the second layer 502.

Optionally, the fourth section 832 is disconnected at the barrier wall 400, so that when the substrate 100 is cut at the fourth section 832 on the first hollow portion 210, cracks generated in the fourth section 832 cannot extend to the third section 831, which ensures reliability of display of the display panel 10.

Referring to FIG. 2, in some optional embodiments, the first hollow portion 210 includes a first opening 211 and a second opening 212 arranged opposite to each other along a thickness direction of the display panel 10, the first opening 211 is located on a side of the second opening 212 facing away from the substrate 100, and an orthographic projection of the second opening 212 on the substrate 100 is within an orthographic projection of the first opening 211 on the substrate 100.

In such optional embodiments, an area of the first opening 211 of the first hollow portion 210 is larger than that of the second opening 212, so that the first hollow portion 210 is completely exposed towards a side facing away from the substrate 100, which facilitates cutting of the substrate 100 in the first hollow portion 210 and can reduce a possibility of cutting of the first insulating layer 200. As a result, the first insulating layer 200 is difficult to crack and extend to the display region 11.

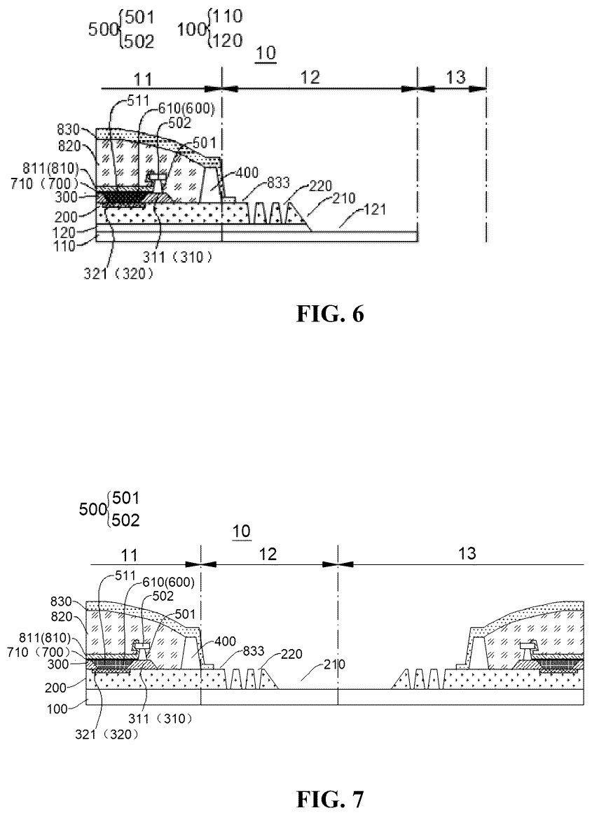

Referring to FIG. 6, FIG. 6 is a sectional view at A-A in FIG. 1 according to still another embodiment.

As shown in FIG. 6, optionally, the substrate 100 includes a base 110 and a protective film 120. The protective film 120 is located on the base 110. The protective film 120 is provided with a fourth recess 121. The fourth recess 121 is in communication with the first hollow portion 210. The protective film 120 is provided with the fourth recess 121, so that the film thickness of the display panel 10 in the transition region 12 is further reduced, which can reduce the difficulty of cutting in the transition region 12. Moreover, at the fourth trench 121, the display panel 10 is thinner, which can reduce a possibility of cracks.

Optionally, the display panel 10 further includes a pixel electrode exposed from the first pixel opening 321, one of the pixel electrode and the first electrode 710 serves as an anode of the first light-emitting unit 610, and the other serves as a cathode of the first light-emitting unit 610. In the embodiments of the present application, for example, the pixel electrode is used as the anode of the first light-emitting unit 610 and the first electrode 710 is used as the cathode of the first light-emitting unit 610.

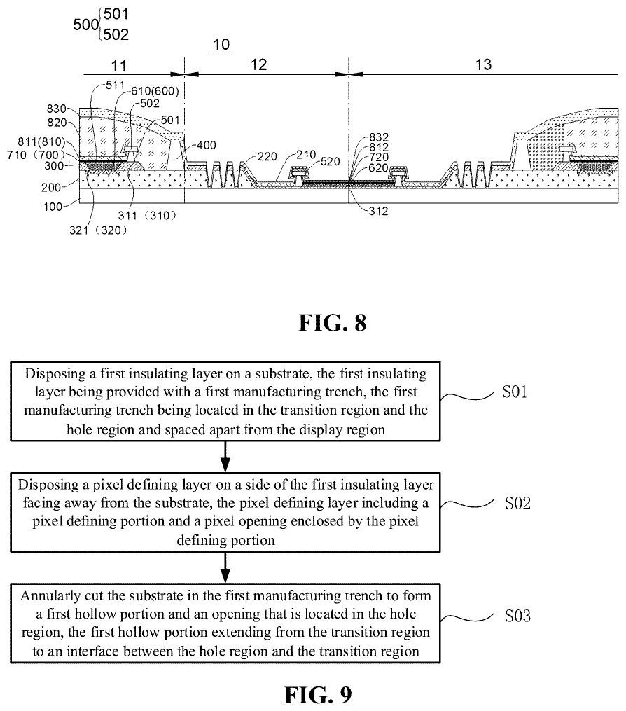

Referring to FIG. 7 and FIG. 8 together, FIG. 7 is a sectional view at A-A in FIG. 1 before cutting according to another embodiment; and FIG. 8 is a sectional view at A-A in FIG. 1 before cutting according to another embodiment.

As shown in FIG. 7 and FIG. 8, FIG. 7 and FIG. 8 show a master before the display panel 10 is cut to form the hole region 13. Taking the master in FIG. 7 and FIG. 8 as an example, the interface of the display panel 10 in the transition region 12 and the hole region 13 is annularly cut, to form the display panel 10 according to the embodiments of the present application.

The structural design in this embodiment may be applied to other display panels 10, and a specific selection may be made according to an actual situation, which is not specifically limited in the present application.

In a second aspect of the present application, an embodiment further provides a display apparatus, including the display panel 10 in any one of the above embodiments in the first aspect. Since the display apparatus provided in the embodiment in the second aspect of the present application includes the display panel 10 in any one of the above embodiments in the first aspect, the display apparatus provided in the embodiment in the second aspect of the present application has the beneficial effects of the display panel 10 in any one of the above embodiments in the first aspect, which is not described in detail again herein.

The display apparatus in the embodiments of the present application includes, but is not limited to, a mobile phone, a personal digital assistant (PDA), a tablet computer, an e-book, a television, access control, a smart fixed phone, a console, and other devices with display functions.

In a third aspect of the present application, an embodiment further provides a method for manufacturing a display panel 10. The display panel 10 may be the display panel 10 provided in any one of the above embodiments in the first aspect. Referring to FIG. 1 and FIG. 8 together with FIG. 9, FIG. 9 is a schematic flowchart of a method for manufacturing a display panel according to an embodiment of the present application. The method includes the following steps.

In step S01, disposing a first insulating layer on a substrate, the first insulating layer being provided with a first manufacturing trench, the first manufacturing trench being located in the transition region and the hole region and spaced apart from the display region.

In step S02, disposing a pixel defining layer on a side of the first insulating layer facing away from the substrate, the pixel defining layer including a pixel defining portion and a pixel opening enclosed by the pixel defining portion.

In step S03, annularly cut the substrate in the first manufacturing trench to form a first hollow portion and an opening that is located in the hole region, the first hollow portion extending from the transition region to an interface between the hole region and the transition region.

According to the method in the embodiment in the third aspect of the present application, through step SO1, the first insulating layer 200 is manufactured on the substrate 100, the first insulating layer 200 is provided with the first manufacturing trench in the transition region 12, and the first manufacturing trench and the display region 11 are spaced apart. Then, through step S02, the pixel defining layer 300 is manufactured, and the pixel opening 320 enclosed by the pixel defining portion 310 is configured to arrange a light-emitting unit to realize light-emitting display of the display panel 10. Finally, through step S03, the substrate 100 is annularly cut in the first manufacturing trench to form an opening in the hole region 13 of the display panel 10, so as to arrange a photosensitive assembly in the hole region 13, which ensures a photosensitive effect of the photosensitive assembly. Since the film thickness of the display panel 10 is smaller at the first manufacturing trench, when the substrate 100 is cut in the first manufacturing trench, it is difficult for the first insulating layer 200 to form cracks and the cracks are difficult to extend to the display region 11, thereby improving use performance of the OLED display panel 10.

In some optional embodiments, the pixel defining portion 310 includes a first pixel defining portion 311 located in the display region 11 and a second pixel defining portion 312 located in the transition region 12, the second pixel defining portion 312 is annular and spaced apart from the first pixel defining portion 311, and at least part of the second pixel defining portion 312 is arranged in the first manufacturing trench. Prior to step S03, the method further includes:
disposing an isolation structure 500 on a side of the pixel defining layer 300 facing away from the substrate 100, the isolation structure 500 including a first isolation portion 510 located on the first pixel defining portion 311 and two second isolation portions 520 spaced apart and located on the second pixel defining portion 312.

In step S03, the method further includes:
annularly cutting the substrate 100 between the two second isolation portions 520.

In such optional embodiments, the first isolation portion 510 is arranged in the display region 11 and the first isolation opening 511 is enclosed by the first isolation portion 510, so as to partition the light-emitting layer 600 to form first light-emitting units 610 disconnected from each other, thereby reducing crosstalk of carriers in the light-emitting layer 600 and improving display effect of the display panel 10. Moreover, the first light-emitting unit 610 may be manufactured without a precision mask, which can reduce development and use of the precision mask and reduce manufacturing costs. The two second isolation portions 520 are spaced apart on the second pixel defining portion 312, so that when the substrate 100 is cut, the substrate 100 may be annularly cut between the two second isolation portions 520, which reduces a possibility of cutting of the first insulating layer 200. As a result, the first insulating layer 200 is difficult to crack and extend to the display region 11.

In some optional embodiments, the display panel 10 further includes a second light-emitting unit 620 on a side of the second isolation portion 520 facing the hole region 13, and in the step of annularly cutting the substrate 100 in the first manufacturing trench, the method further includes:
annularly cutting the substrate 100 on the second light-emitting unit 620.

In such optional embodiments, the light-emitting layer 600 is disconnected at the second isolation structure 500 to form the second light-emitting unit 620, so that a film layer structure between the two second isolation portions 520 is close to the film structure for cutting in the related art, and when the substrate 100 is cut on the second light-emitting unit 620, the substrate 100 can be cut using an existing cutting device and known device parameters, reducing the difficulty of cutting.

In some optional embodiments, the display panel 10 further includes a second electrode 720 on a side of the second isolation portion 520 facing the hole region 13, and in step S03, the method further includes:
annularly cutting the substrate 100 on the second electrode 720.

In such optional embodiments, the first electrode layer 700 is disconnected at the second isolation structure 500 to form the second electrode 720, so that the film layer structure between the two second isolation portions 520 is close to the film structure for cutting in the related art, and when the substrate 100 is cut on the second electrode 720, the substrate 100 can be cut using an existing cutting device and known device parameters, reducing the difficulty of cutting.

In some optional embodiments, prior to step S03, the method further includes:
disposing a first encapsulation material layer on the side of the pixel defining layer 300 facing away from the substrate 100, patterning the first encapsulation material layer to obtain a first section 811 located in the display region 11 and a second section 812 located in the transition region 12 and the hole region 13, and at least part of the second section 812 being located in the first hollow portion 210.

In step S03, the method further includes:
annularly cutting the substrate 100 on the second section 812.

In such optional embodiments, the second section 812 of the first encapsulation layer 810 is arranged in the first manufacturing trench, so that a film layer structure in the first manufacturing trench is close to the film structure for cutting in the related art, and the substrate 100 can be cut using an existing cutting device and known device parameters, reducing the difficulty of cutting.

In some optional embodiments, prior to step S03, the method further includes:
disposing a third encapsulation material layer on the side of the second section 812 facing away from the substrate 100, patterning the third encapsulation material layer to obtain a third section 831 located in the display region 11 and a fourth section 832 located in the transition region 12 and the hole region 13, and at least part of the fourth section 832 being located in the first hollow portion 210.

In step S03, the method further includes:
annularly cutting the substrate 100 on the fourth section 832.

In such optional embodiments, the fourth section 832 of the third encapsulation layer 830 is arranged in the first manufacturing trench, so that the film layer structure in the first manufacturing trench is close to the film structure for cutting in the related art, and the substrate 100 can be cut using an existing cutting device and known device parameters, reducing the difficulty of cutting.

Optionally, after the step of disposing a first encapsulation material layer on the side of the pixel defining layer 300 facing away from the substrate 100, the method further includes:
disposing a second encapsulation material layer on a side of the first encapsulation material layer facing away from the substrate 100; and
disposing a third encapsulation material layer on a side of the second encapsulation material layer facing away from the substrate 100, and patterning the third encapsulation material layer to remove at least part of the third encapsulation material layer in the transition region 12 and the hole region 13 to obtain a third encapsulation layer 830, the third encapsulation layer 830 including a second hollow portion 833 located in the transition region 12. In such optional embodiments, after the third encapsulation material layer is manufactured, the third encapsulation material layer is cut in the transition region 12 and the hole region 13, so that the third encapsulation material layer in the transition region 12 and the hole region 13 is removed and the second hollow portion 833 is formed. As a result, the brittle film layer of the display panel 10 is thinned at the second hollow portion 833 of the transition region 12 and the hole region 13, and when the substrate 100 is cut at the second hollow portion 833, it is difficult for the third encapsulation layer 830 to form cracks and the cracks are difficult to extend to the display region 11.

The first hole 833 configured to avoid cutting damage mentioned below is the second hollow portion 833 mentioned above.

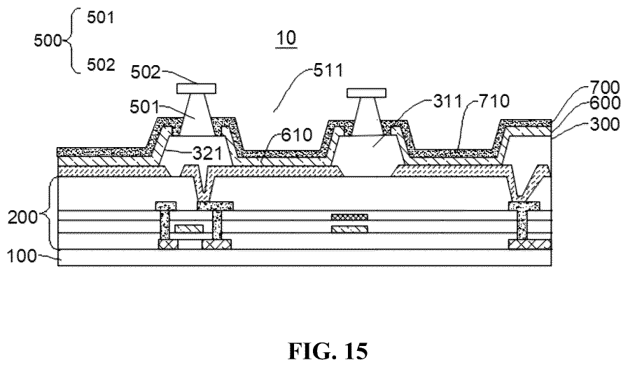

Referring to FIGS. 1, 2, and 15 together. FIG. 15 is a partial sectional view of a display region of a display panel according to an embodiment of the present application.

As shown in FIGS. 1, 2, and 15, the embodiments of the present application provide a display panel 10, which comprises a display region 11, a transition region 12, and a hole region 13. The display region 11 is disposed around the transition region 12, and the transition region 12 is disposed around the hole region 13. The display panel 10 further comprises a substrate 100, a first insulating layer 200, a pixel defining layer 300 and a light-emitting layer 600. The first insulating layer 200 is located on the substrate 100, and the first insulating layer 200 is provided with a first hollow portion 210. The first hollow portion 210 is located in the transition region 12 and is spaced apart from the display region 11. The first hollow portion 210 extends from the transition region 12 to an interface between the hole region 13 and the transition region 12. The pixel defining layer 300 is located on a side of the first insulating layer 200 facing away from the substrate 100. The pixel defining layer 300 includes a pixel defining portion 310 and a pixel opening 320 enclosed by the pixel defining portion 310. The light-emitting layer 600 includes a light-emitting unit located within the pixel opening 320.

Optionally, the interface is a cutting edge of the hole region 13 of the display panel 10, and the hole region 13 is formed by cutting the display panel 10 at the interface.

According to an embodiment of the present application, the display panel 10 comprises a display region 11, a transition region 12, and a hole region 13. The display region 11 is disposed around the transition region 12, and the transition region 12 is disposed around the hole region 13. The display region 11 is configured to realize light-emitting display of the display panel 10, and the hole region 13 is configured to arrange a photosensitive assembly under the display panel. The display panel 10 further includes a substrate 100, a first insulating layer 200, and a pixel defining layer 300. The pixel defining layer 300 includes a pixel defining portion 310 and a pixel opening 320 enclosed by the pixel defining portion 310, and the pixel opening 320 is configured to arrange a light-emitting unit. A first hollow portion 210 is provided on the first insulating layer 200 between the pixel defining layer 300 and the substrate 100. The first hollow portion 210 is located in the transition region 12 and is spaced apart from the display region 11, so that a brittle film layer of the display panel 10 at the first hollow portion 210 is thinned or removed, and when the substrate 100 is cut at the first hollow portion 210, it is difficult for the first insulating layer 200 to form cracks and the cracks are difficult to extend to the display region 11, thereby improving use performance of an OLED display panel 10.

As shown in FIG. 15, optionally, the display panel 10 includes an array layer on the substrate 100, and the first insulating layer 200 includes an interlayer insulating layer located within the array layer. For example, the array layer includes a metal layer, which includes a first metal layer, a second metal layer, and a third metal layer arranged in stack. The first insulating layer 200 includes an interlayer insulating layer between adjacent metal layers. The display panel 10 includes a pixel driving circuit, the pixel driving circuit includes transistors and storage capacitors. The transistors include semiconductors, gates, sources, and drains. The storage capacitors include first electrode plates and second electrode plates. As an example, the gate and first electrode plate may be located in the first metal layer, the second electrode plate may be located in the second metal layer, and the source and drain electrodes may be located in the third metal layer.

For example, the array layer includes an active layer and a gate layer, with the gate layer being the first metal layer mentioned above. Optionally, the first insulating layer 200 includes an inter-gate insulating layer between the active layer and the gate layer.

Optionally, the first insulating layer 200 includes a planarization layer located on a side of the pixel defining layer 300 facing the substrate 100.

In some optional embodiments, the display panel 10 further includes a first encapsulation layer 810, the first encapsulation layer 810 is located on a side of the pixel defining layer 300 facing away from the substrate 100. The first encapsulation layer 810 includes a first section 811 located in the display region 11.

In such optional embodiments, the first encapsulation layer 810 encapsulates the first electrode layer 700 and the light-emitting layer 600 to reduce erosion of water and oxygen on the first electrode layer 700 and the light-emitting layer 600. The first section 811 of the first encapsulation layer 810 is located in the display region 11, which improves encapsulation performance of the display panel 10 in the display region 11.

Optionally, a portion of the first encapsulation layer 810 in the transition region 12 may be etched to further reduce the film layer thickness of the display panel 10 in the transition region 12 and reduce the difficulty of cutting. In some optional embodiments, the display panel 10 further includes a second encapsulation layer 820. The second encapsulation layer 820 is located on a side of the first encapsulation layer 810 facing away from the substrate 100 and on a side of the barrier wall 400 facing away from the transition region 12.

In such optional embodiments, the first encapsulation layer 810 and the second encapsulation layer 820 are used in the display panel 10 for multi-layer encapsulation, which further improves the encapsulation performance of the display panel 10. The second encapsulation layer 820 is blocked at the barrier wall 400 so that each second encapsulation layer 820 is located in the display region 11, which can alleviate the problem of water and oxygen intrusion due to entry of water vapor into the display region 11 from the transition region 12.

In some optional embodiments, the display panel 10 further includes a third encapsulation layer 830. The third encapsulation layer 830 is located on a side of the second encapsulation layer 820 facing away from the substrate 100. At least one of the first encapsulation layer 810 and the third encapsulation layer 830 is provided with a blocking trench 840 or a first hole 833 configured to avoid cutting damage.

In such optional embodiments, the first encapsulation layer 810, the second encapsulation layer 820, and the third encapsulation layer 830 are used in the display panel 10 for multi-layer encapsulation, which further improves the encapsulation performance of the display panel 10. When cutting the hole region 13, the impact of cutting the hole region 13 on the first encapsulation layer 810 and/or the third encapsulation layer 830 can be reduced, avoiding the problem of cutting to the first encapsulation layer 810 and/or the third encapsulation layer 830 causing cracks in the first encapsulation layer 810 and/or the third encapsulation layer 830 and extending to the display region 11. The blocking trench 840 divides the first encapsulation layer 810 and/or the third encapsulation layer 830 into a plurality of sections. When a section near the hole region 13 is cut and a crack is generated, an extension path for the crack is blocked by blocking trench 840, thereby avoiding the crack from extending to the display region 11.

Optionally, the first encapsulation layer 810 includes an inorganic material. The first encapsulation layer 810 is encapsulated using the inorganic material. The first encapsulation layer 810 made of the inorganic material is denser and has better encapsulation performance.

Optionally, the second encapsulation layer 820 includes an organic material. The second encapsulation layer 820 is encapsulated using the organic material, which further improves encapsulation performance of the encapsulation layer.

Optionally, the third encapsulation layer 830 includes an inorganic material. The first encapsulation layer 810, the second encapsulation layer 820, and the third encapsulation layer 830 are encapsulated by using the inorganic material, the organic material, and the inorganic material respectively, to form a thin film encapsulation (Thin Film Encapsulation, TFE) structure, which further improves encapsulation performance of the encapsulation layers.

As shown in FIG. 4, optionally, the isolation structure 500 includes a second isolation portion 520 located in the transition region, the second isolation portion 520 is spaced apart from the hole region 13. The second isolation portion 520 is spaced apart from the hole region 13 refers to a certain distance is set between the second isolation portion 520 and the hole region 13.

Optionally, the second isolation portion 520 is located in the first hollow portion 210, and the second isolation portion 520 is located in the first hollow portion 210 of the transition region 12 to isolate the film layer of the transition region 12 and reduce the extension of cracks of the film layer of the transition region 12 caused by cutting towards the display region 11.

Patent/patent application No. PCT/CN2023/134518, 202310759370.2, 202311117143.6, 202310771071.0, 202310740412.8, 202310707209.0, 202310771124.9, 202310855866. X, 202311017132.0, 20231114847.6, 202311091555.7 recite the relevant technical solutions of the isolation structure (also known as partition structure, etc.) for reference.

In some optional embodiments, the first encapsulation layer 810 includes a second section 812 located in the transition region 12, and at least part of the second section 812 is located in the first hollow portion 210.

In such optional embodiments, the second section 812 of the first encapsulation layer 810 is arranged in the first hollow portion 210, so that the film layer structure in the first hollow portion 210 is close to the film structure for cutting in the related art, and the substrate 100 can be cut using an existing cutting device and known device parameters, reducing the difficulty of cutting.

Optionally, the second section 812 is divided by the second isolation portion 520 to form two or more disconnected sub sections, and a blocking trench 840 is formed between adjacent sub sections on the isolation structure 500. When cutting the transition region 12, a crack is generated in the second section 812, and adjacent sub sections are separated by the blocking trench 840, so that the crack cannot extend and transmit between the sub sections, reducing the possibility of cracks transmitting from the second section 812 to the display region 11.

In some optional embodiments, the second section 812 includes first thinned portions 813 located on two sides of the second isolation portion 520.

In such optional embodiments, the second section 812 is provided with the first thinned portions 813 on at least one side of the second isolation portion 520, that is, the second section 812 is thinner on the at least one side of the second isolation portion 520, so that when the substrate 100 is cut on a side of the second isolation portion 520 facing the hole region 13, generated cracks are easily broken at the first thinned portions 813 and are difficult to continuously extend to the display region 11.

Optionally, the second section 812 and the first section 811 are spaced apart, so that when the substrate 100 is cut at the second section 812 on the first hollow portion 210, cracks generated in the second section 812 cannot extend to the first section 811, which ensures reliability of display of the display panel 10. In some optional embodiments, the third encapsulation layer 830 includes a first hole 833 located in the transition region 12, and an orthogonal projection of the first hollow portion 210 on the substrate 100 is at least partially overlapped with an orthogonal projection of the first hole 833 on the substrate 100.

In such optional embodiments, the orthographic projections of the first hollow portion 210 and the first hole 833 on the substrate 100 are at least partially overlapped with each other, so that the first hollow portion 210 and the first hole 833 are at least partially in communication. At an overlapping position, the display panel 10 has a smaller thickness, making it easier to cut the display panel 10 at the overlapping position. Moreover, it is difficult for the third encapsulation layer 830 and the first insulating layer 200 to form cracks and the cracks are difficult to extend to the display region 11.

In some optional embodiments, the orthographic projection of the first hollow portion 210 on the substrate 100 is within the orthographic projection of the first hole 833 on the substrate 100.

In such optional embodiments, an orthographic projection area of the first hole 833 is larger than that of the first hollow portion 210, so that when the substrate 100 is cut in the first hollow portion 210, the thickness is lower and the difficulty of cutting is low. Moreover, since the first hole 833 has a larger area, it is more difficult for the third encapsulation layer 830 to form cracks and extend to the display region 11.

In some optional embodiments, the first hollow portion 210 is arranged running through the first insulating layer 200 along a thickness direction of the display panel 10.

In such optional embodiments, the first hollow portion 210 is arranged running through the first insulating layer 200, which further reduces the thickness of the first insulating layer 200 at the first hollow portion 210 and reduces the difficulty of cutting the substrate 100 at the first hollow portion 210. Moreover, when the substrate 100 is cut at the first hollow portion 210, it is more difficult for the first insulating layer 200 to form cracks and extend to the display region 11, which improves reliability of light emission of the display panel 10.

As shown in FIG. 3, in some optional embodiments, the first insulating layer 200 is provided with a third hollow portion 220 located in the transition region 12, and the third hollow portion 220 is arranged around the first hollow portion 210 and spaced apart from the first hollow portion 210.

In such optional embodiments, the third hollow portion 220 is arranged around the first hollow portion 210, so that, when the first insulating layer 200 is provided with another film layer, the arrangement of the third hollow portion 220 can increase a path of water and oxygen intrusion, making it more difficult for water and oxygen to intrude into the display region 11 through the transition region 12 and ensuring reliability of the display panel 10.

Optionally, a plurality of third hollow portions 220 are spaced apart. The arrangement of the plurality of third hollow portions 220 can further increase the path of water and oxygen intrusion.

Optionally, the third encapsulation layer 830 and/or the first encapsulation layer 810 is arranged to cover side and bottom walls of the third hollow portion 220, thereby increasing edge length of the extension path of the third encapsulation layer 830 and/or the first encapsulation layer 810 and further increasing the water oxygen intrusion path.

As shown in FIG. 4 and FIG. 5, optionally, the pixel defining layer 300 includes a second pixel defining portion 312 located within the first hollow portion 210; the second isolation unit 520 is located on the second pixel limiting unit 312, the second pixel defining unit 312 inside the first hollow unit 210 is retained, so that the film layer structure in the first hollow portion 210 is close to the film structure for cutting in the related art, and the substrate 100 can be cut using an existing cutting device and known device parameters, reducing the difficulty of cutting.

In some optional embodiments, the pixel defining layer 300 further includes a first pixel defining portion 311 located in the display region 11, and the pixel opening 320 includes a first pixel opening 321 enclosed by the first pixel defining portion 311.

Optionally, The display panel 10 further includes a barrier wall 400, the barrier wall 400 is located on a side of the first insulating layer 200 facing away from the substrate 100, and the barrier wall 400 is arranged between the first pixel defining portion 311 and the first hollow portion 210 and forms an annular shape and surrounds the transition region 12.

In such optional embodiments, the first pixel defining portion 311 is located in the display region 11 to define a light-emitting region of the display region 11. That is, the first pixel opening 321 is enclosed by the first pixel defining portion 311, so that the display panel 10 emits light at the first pixel opening 321. The barrier wall 400 is arranged between the first pixel defining portion 311 and the first hollow portion 210, and the barrier wall 400 allows a portion of a film layer to be arranged in the display region 11 and blocked at the position of the barrier wall 400, which can alleviate the problem of water and oxygen intrusion due to entry of water vapor into the display region 11 from the transition region 12.

As shown in FIG. 3, optionally, two or more barrier walls 400 are disposed and spaced apart. The arrangement of the plurality of barrier walls 400 can further extend a path of water and oxygen intrusion and alleviate the problem of water and oxygen intrusion due to entry of water vapor into the display region 11 from the transition region 12.

In some optional embodiments, the isolation structure 500 is located on a side of the pixel defining portion 310 facing away from the substrate 100. The isolation structure 500 includes a first isolation portion 510 located on a side of the barrier wall 400 facing away from the transition region 12. A first isolation opening 511 is enclosed by the first isolation portion 510, and the first pixel opening 321 is in communication with the first isolation opening 511.

As shown in FIG. 4 and FIG. 5, optionally, the light-emitting unit comprises a first light-emitting unit 610 located in the first isolation opening 511.

In such optional embodiments, the first isolation portion 510 is arranged in the display region 11 and a plurality of first isolation openings 511 are enclosed by the first isolation portion 510 so as to partition the light-emitting layer 600 to form a plurality of first light-emitting units 610 disconnected from each other, thereby reducing crosstalk of carriers in the light-emitting layer 600 and improving display effect of the display panel 10. Moreover, the first light-emitting unit 610 may be manufactured without a precision mask, which can reduce development and use of the precision mask so as to reduce manufacturing costs.

Optionally, a portion of the light-emitting layer 600 may be etched to form a hollow in the transition region 12 to further reduce the film layer thickness of the display panel 10 in the transition region 12 so as to reduce difficulty of cutting.

In some optional embodiments, the display panel 10 further includes a first electrode layer 700. The first electrode layer 700 is located on a side of the light-emitting layer 600 facing away from the substrate 100. The first electrode layer 700 includes a first electrode 710 located in the first isolation opening 511.

In such optional embodiments, the first electrode layer 700 is partitioned by the first isolation portion 510 to form first electrodes 710 spaced apart from each other. Each of the first electrodes 710 is located in the first isolation opening 511. The first electrodes 710 spaced apart from each other are electrically connected through the first isolation portion 510 to form an entire-surface electrode.

Optionally, the first electrode layer 700 maybe partially be etched in the transition region 12 to further reduce the film layer thickness of the display panel 10 in the transition region 12 so as to reduce the difficulty of cutting.

Optionally, the light-emitting layer 600 includes a second light-emitting unit 620 located on a side of the second isolation portion 520 facing the hole region 13.

In such optional embodiments, the second pixel defining portion 312 and the second isolation portion 520 are arranged in the first hollow portion 210, and the second light-emitting unit 620 is provided on the side of the second isolation portion 520 facing the hole region 13, so that a film layer structure in the first hollow portion 210 is close to the film structure for cutting in the related art, and the substrate 100 can be cut using an existing cutting device and known device parameters, reducing the difficulty of cutting.

Optionally, the first electrode layer 700 includes a second electrode 720 on the side of the second isolation portion 520 facing the hole region 13, and the second electrode 720 is provided on the side of the second isolation portion 520 facing the hole region 13, so that the film layer structure in the first hollow portion 210 is close to the film structure for cutting in the related art, and the substrate 100 can be cut using an existing cutting device and known device parameters, reducing the difficulty of cutting.

Optionally, the third encapsulation layer 830 includes a third section 831 located in the display region 11 and a fourth section 832 located in the transition region 12, and at least part of the fourth section 832 is located in the first hollow portion 210. The fourth section 832 of the third encapsulation layer 830 is arranged in the first hollow portion 210, so that the film layer structure in the first manufacturing trench is close to the film structure for cutting in the related art, and the substrate 100 can be cut using an existing cutting device and known device parameters, reducing the difficulty of cutting.

Optionally, the fourth section 832 includes second thinned portions 834 on the two sides of the second isolation portion 520, that is, the fourth portion 832 is thinner on the two sides of the second isolation portion 520, so that when the substrate 100 is cut on the side of the second isolation portion 520 facing the hole region 13, generated cracks are easily broken at the second thinned portions 834 and are difficult to continuously extend to the display region 11.

As shown in FIG. 4, optionally, the isolation structure 500 includes a first layer 501, and each first electrode 710 is electrically connected to the first layer 501. The first electrodes 710 spaced apart from each other are electrically connected through the first layer 501 to form an entire-surface electrode. The first electrodes 710 and the first layer 501 are more easily overlapped, thereby improving overlap efficiency of the first electrodes 710.

In some optional embodiments, the isolation structure 500 further includes a second layer 502 located on a side of the first layer 501 facing away from the substrate 100, and an orthographic projection of the first layer 501 on the substrate 100 is within an orthographic projection of the second layer 502 on the substrate 100.

In such optional embodiments, the first layer 501 and the second layer 502 are arranged to form the isolation structure 500, the orthographic projection of the first layer 501, which is arranged close to the substrate 100 on the substrate 100, is within the orthographic projection of the second layer 502 on the substrate 100, an area of the second layer 502 is larger than that of the first layer 501, and the second layer 502 covers a surface of the first layer 501 close to the second layer 502. In this case, the first layer 501 is recessed relative to the second layer 502 in a direction away from the pixel opening 320. When the light-emitting layer 600 is manufactured, the light-emitting layer 600 has a large gap at an edge of the isolation structure 500, and the first layer 501 is concave relative to the second layer 502. The light-emitting layer 600 is difficult to connect at the edge of the isolation structure 500, resulting in breakage. The light-emitting layer 600 is broken to form the first light-emitting unit 610 and the second light-emitting unit 620 disconnected from each other. Moreover, the second layer 502 is concave relative to the first layer 501. When the first encapsulation layer 810 and the third encapsulation layer 830 are manufactured, the second section 812 is provided with thinner first thinned portions 813 on two sides of the second layer 502, and the fourth section 832 is provided with thinner second thinned portions 834 on the two sides of the second layer 502.

Optionally, the fourth section 832 is disconnected at the barrier wall 400, so that when the substrate 100 is cut at the fourth section 832 on the first hollow portion 210, cracks generated in the fourth section 832 cannot extend to the third section 831, which ensures reliability of display of the display panel 10.

Referring to FIG. 2, in some optional embodiments, the first hollow portion 210 includes a first opening 211 and a second opening 212 arranged opposite to each other along a thickness direction of the display panel 10, the first opening 211 is located on a side of the second opening 212 facing away from the substrate 100, and an orthographic projection of the second opening 212 on the substrate 100 is within an orthographic projection of the first opening 211 on the substrate 100.

In such optional embodiments, an area of the first opening 211 of the first hollow portion 210 is larger than that of the second opening 212, so that the first hollow portion 210 is completely exposed towards a side facing away from the substrate 100, which facilitates cutting of the substrate 100 in the first hollow portion 210 and can reduce a possibility of cutting of the first insulating layer 200. As a result, the first insulating layer 200 is difficult to crack and extend to the display region 11.

As shown in FIG. 6, optionally, the substrate 100 includes a base 110 and a protective film 120. The protective film 120 is located on the base 110. The protective film 120 is provided with a fourth recess 121. The fourth recess 121 is in communication with the first hollow portion 210. The protective film 120 is provided with the fourth recess 121, so that the film thickness of the display panel 10 in the transition region 12 is further reduced, which can reduce the difficulty of cutting in the transition region 12. Moreover, at the fourth trench 121, the display panel 10 is thinner, which can reduce a possibility of cracks.

Optionally, the display panel 10 further includes a pixel electrode exposed from the first pixel opening 321, one of the pixel electrode and the first electrode 710 serves as an anode of the first light-emitting unit 610, and the other serves as a cathode of the first light-emitting unit 610. In the embodiments of the present application, for example, the pixel electrode is used as the anode of the first light-emitting unit 610 and the first electrode 710 is used as the cathode of the first light-emitting unit 610.

As shown in FIG. 7 and FIG. 8, FIG. 7 and FIG. 8 show a master before the display panel 10 is cut to form the hole region 13. Taking the master in FIG. 7 and FIG. 8 as an example, the interface of the display panel 10 in the transition region 12 and the hole region 13 is annularly cut, to form the display panel 10 according to the embodiments of the present application. Cutting path is not shown in the drawings. The interface between the transition region 12 and the hole region 13 serves as the boundary of the cutting path, while the other boundary is separated by a certain width from the interface.

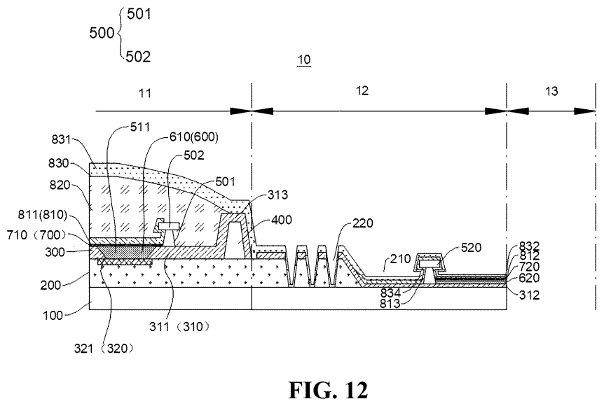

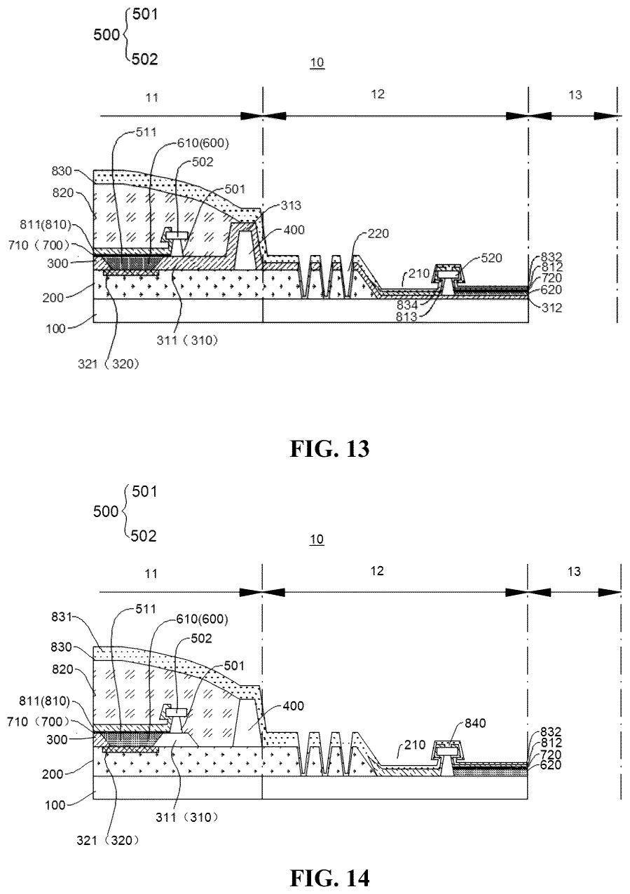

Referring to FIG. 12 and FIG. 13. FIG. 12 is a sectional view at A-A in FIG. 1 according to still another embodiment; FIG. 13 is a sectional view at A-A in FIG. 1 according to still another embodiment.

As shown in FIG. 12, optionally, the pixel defining portion 310 further includes an extension portion 313 connected to the first pixel defining portion 311. At least a portion of the extension portion 313 is located on a surface of the barrier wall 400 facing away from the substrate 100, which raises a subsequent portion of the third encapsulation layer 830 on the barrier wall 400, reduces the slope of the third encapsulation layer 830, and improves the encapsulation performance of the third encapsulation layer 830.

As shown in FIG. 13, optionally, the extension portion 313 extends to the transition region 12, further increasing the intrusion path of water and oxygen in the extension portion 313 and reducing the water and oxygen intrusion into the display region 11.

Optionally, the extension portion 313 is spaced apart from the second pixel defining portion 312, making it difficult for the cracks generated during the cutting of the second pixel defining portion 312 to extend towards the extension portion 313.

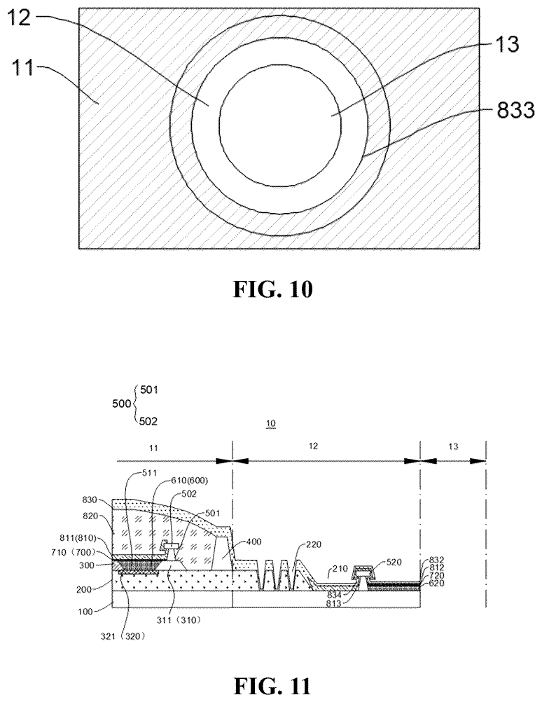

Referring to FIG. 2 and FIG. 10 together. FIG. 10 is a partial top view of a display panel according to an embodiment of the present application.

As shown in FIG. 2 and FIG. 10, the present embodiment provides a display panel 10, the display panel 10 comprises a display region 11, a hole region 13, and a transition region 12 located between the display region 11 and the hole region 13. The display panel 10 further comprises: a substrate 100; a pixel defining layer 300 located on a side of the substrate 100, the pixel defining layer 300 includes a pixel defining portion 310 and a pixel opening 320 enclosed by the pixel defining portion 310; a light emitting layer 600, including a light emitting unit located within the pixel opening 320; an inorganic encapsulation layer located on a side of the light-emitting unit facing away from the substrate 100. The inorganic encapsulation layer includes a first hole 833 at least partially located in the hole region 13, and the hole region 13 is within the first hole 833.

According to the embodiment of the present application, the display panel 10 comprises a display region 11, a transition region 12, and a hole region 13. The display region 11 is arranged around the transition region 12, and the transition region 12 is arranged around the hole region 13. The display region 11 is configured to realize light-emitting display of the display panel 10, and a photosensitive assembly is arranged in the hole region 13 under the display panel 10. The display panel 10 further includes a substrate 100, a pixel defining layer 300, and a first encapsulation layer 810. The pixel defining layer 300 includes a pixel defining portion 310 and a pixel opening 320 enclosed by the pixel defining portion 310. The pixel opening 320 is configured to arrange a light-emitting unit. The first encapsulation layer 810 encapsulates the first electrode layer 700 and the light-emitting layer 600 to reduce erosion of water and oxygen on the first electrode layer 700 and the light-emitting layer 600. The first section 811 of the first encapsulation layer 810 is located in the display region 11, which improves encapsulation performance of the display panel 10 in the display region 11. A first hole 833 is disposed on the inorganic encapsulation layer to reduce the film thickness of the display panel 10 at the cutting path, in order to reduce the difficulty of cutting the hole region 13. The hole region 13 is within the first hole 833. When cutting the hole region 13, the impact of cutting the hole region 13 on the inorganic encapsulation layer can be reduced, avoiding the problem of cutting to the inorganic encapsulation layer causing cracks in the inorganic encapsulation layer and extending to the display region 11.

Optionally, the inorganic encapsulation layer includes a first encapsulation layer 810 and a third encapsulation layer 830. The third encapsulation layer 830 is located on a side of the first encapsulation layer 810 facing away from the substrate 100, and the first hole 833 is disposed on the first encapsulation layer 810 and/or the third encapsulation layer 830. When cutting the hole region 13, the impact of cutting the hole region 13 on the first encapsulation layer 810 and/or the third encapsulation layer 830 can be reduced, avoiding the problem of cutting to the first encapsulation layer 810 and/or the third encapsulation layer 830 causing cracks in the first encapsulation layer 810 and/or the third encapsulation layer 830 and extending to the display region 11.

Referring to FIG. 14, which is a sectional view at A-A in FIG. 1 according to still another embodiment.

As shown in FIG. 14, the optional inorganic encapsulation layer includes a blocking trench 840 located in the transition region 12. The blocking trench 840 divides the inorganic encapsulation layer into a plurality of sections. When a section near the hole region 13 is cut to produce a crack, an extension path for the crack is blocked by the blocking trench 840, thereby avoiding the crack from extending to the display region 11.

Optionally, the blocking trench 840 surrounds the hole region 13 and in an annular shape. The blocking trench 840 separates the inorganic encapsulation layer on each side of the hole region 13, further preventing cracks from extending to the display region 11.

Optionally, the blocking trench 840 is disposed on the first encapsulation layer 810, and the first hole 833 is disposed on the third encapsulation layer 830. When cutting the hole region 13, the impact of cutting the hole region 13 on the third encapsulation layer 830 can be reduced, avoiding the problem of cutting to the third encapsulation layer 830 causing cracks in the third encapsulation layer 830 and extending to the display region 11. The blocking trench 840 divides the third encapsulation layer 830 into a plurality of sections. When a section near the hole region 13 is cut and a crack is generated, an extension path for the crack is blocked by blocking trench 840, thereby avoiding the crack from extending to the display region 11.

Optionally, the blocking trench 840 is arranged running through the first encapsulation layer 810 along a thickness direction of the display panel 10, so that the first encapsulation layer 810 is completely separated by the blocking trench 840, thereby further avoiding cracks from extending to the display region 11 on the first encapsulation layer 810.

Optionally, the first hole 833 is arranged running through the third encapsulation layer 830 along the thickness direction of the display panel 10, so that the third encapsulation layer 830 is completely hollowed out in the first hole 833, further avoiding the problem of cutting to the third encapsulation layer 830 and causing cracks in the third encapsulation layer 830 during cutting.

As shown in FIG. 13 and FIG. 14, optionally, the display panel 10 further includes an isolation structure 500 located on the substrate 100. The isolation structure 500 includes a second isolation portion 520 located in the transition region 12, the second isolation portion 520 is spaced apart from the hole region 13. The blocking trench 840 is located on a side of the second isolation portion 520 facing away from the substrate 100. The second isolation portion 520 divides the inorganic encapsulation layer to form a blocking trench 840, which divides the inorganic encapsulation layer into a plurality of sections. When a section near the hole region 13 is cut and a crack is generated, an extension path for the crack is blocked by blocking trench 840, thereby avoiding the crack from extending to the display region 11.

In some optional embodiments, the display panel 10 further comprises: a first insulating layer 200 located on the substrate 100. The first insulating layer 200 is provided with a first hollow portion 210, the first hollow portion 210 is located in the transition region 12 and spaced apart from the display region 11, and the first hollow portion 210 extends from the transition region 12 to an interface between the hole region 13 and the transition region 12.

In such optional embodiments, a first insulating layer 200 located between the pixel defining layer 300 and the substrate 100 is provided with a first hollow portion 210. The first hollow portion 210 is located in the transition region 12 and spaced apart from the display region 11, so that a brittle film layer of the display panel 10 at the first hollow portion 210 is thinned or removed, and when the substrate 100 is cut at the first hollow portion 210, it is difficult for the first insulating layer 200 to form cracks and the cracks are difficult to extend to the display region 11, thereby improving use performance of an OLED display panel 10.

Optionally, the first hollow portion 210 is arranged running through the first insulating layer 200 along the thickness direction of the display panel 10, so that the first insulating layer 200 is completely separated by the first hollow portion 210, thereby further avoiding cracks from extending to the display region 11 on the first insulating layer 200.

Optionally, the first hollow portion 210 surrounds the hole region 13 and in an annular shape. The first hollow portion 210 separates the first insulating layer 200 on each side of the hole region 13, further preventing cracks on the first insulating layer 200 from extending to the display region 11.

Optionally, the first hole 833 is located in the transition region 12. When cutting the transition region 12, it is necessary to avoid cutting into the inorganic encapsulation layer where the first hole 833 is located, which may cause cracks in the inorganic encapsulation layer.

Optionally, the third hollow portion 220 surrounds the hole region 13 and in an annular shape. The third hollow portion 220 separates the first insulating layer 200 again around the hole region 13, further preventing cracks on the first insulating layer 200 from extending to the display region 11.

As shown in FIG. 13 and FIG. 14, the present embodiment provides a display panel 10, the display panel 10 comprises a display region 11, a hole region 13, and a transition region 12 located between the display region 11 and the hole region 13. The display panel 10 further comprises: a substrate 100; a first insulating layer 200 located on the substrate 100, the first insulating layer 200 is provided with a first hollow portion 210, the first hollow portion 210 is located in the transition region 12 and is spaced apart from the display region 11, and the first hollow portion 210 extends from the transition region 12 to an interface between the hole region 13 and the transition region 12; a pixel defining layer 300 located on a side of the substrate 100, the pixel defining layer 300 includes a pixel defining portion 310 and a pixel opening 320 enclosed by the pixel defining portion 310; a light emitting layer 600, including a light emitting unit located within the pixel opening 320; an inorganic encapsulation layer located on a side of the pixel defining layer 300 facing away from the substrate 100, the inorganic encapsulation layer includes a blocking trench 840 located in the transition region 12.

According to the embodiment of the present application, the display panel 10 comprises a display region 11, a transition region 12, and a hole region 13. The display region 11 is arranged around the transition region 12, and the transition region 12 is arranged around the hole region 13. The display region 11 is configured to realize light-emitting display of the display panel 10, and a photosensitive assembly is arranged in the hole region 13 under the display panel 10. The display panel 10 further includes a substrate 100, a first insulating layer 200, a pixel defining layer 300, and a first encapsulation layer 810. The pixel defining layer 300 includes a pixel defining portion 310 and a pixel opening 320 enclosed by the pixel defining portion 310. The pixel opening 320 is configured to arrange a light-emitting unit. A first insulating layer 200 located between the pixel defining layer 300 and the substrate 100 is provided with a first hollow portion 210. The first hollow portion 210 is located in the transition region 12 and spaced apart from the display region 11, so that a brittle film layer of the display panel 10 at the first hollow portion 210 is thinned or removed, and when the substrate 100 is cut at the first hollow portion 210, it is difficult for the first insulating layer 200 to form cracks and the cracks are difficult to extend to the display region 11, thereby improving use performance of an OLED display panel 10. The first encapsulation layer 810 encapsulates the first electrode layer 700 and the light-emitting layer 600 to reduce erosion of water and oxygen on the first electrode layer 700 and the light-emitting layer 600. The first section 811 of the first encapsulation layer 810 is located in the display region 11, which improves encapsulation performance of the display panel 10 in the display region 11. The blocking trench 840 divides the inorganic encapsulation layer into a plurality of sections. When a section near the hole region 13 is cut to produce a crack, an extension path for the crack is blocked by the blocking trench 840, thereby avoiding the crack from extending to the display region 11.

Optionally, the inorganic encapsulation layer includes a first encapsulation layer 810 and a third encapsulation layer 830. A blocking trench 840 is provided on the first encapsulation layer 810 and/or the third encapsulation layer 830. The blocking trench 840 divides the first encapsulation layer 810 and/or the third encapsulation layer 830 into a plurality of sections. When a section near the hole region 13 is cut and a crack is generated, an extension path for the crack is blocked by blocking trench 840, thereby avoiding the crack from extending to the display region 11. Optionally, the blocking trench 840 surrounds the hole region 13 and in an annular shape, making it difficult for the cracks generated by the inorganic encapsulation layer around the hole region 13 to extend to the display region 11.

Optionally, a plurality of blocking trenches 840 are disposed to further prevent cracks from extending to display region 11.

Optionally, the blocking trench 840 is disposed on the first encapsulation layer 810, and the first hole 833 is disposed on the third encapsulation layer 830. When cutting the hole region 13, the impact of cutting the hole region 13 on the third encapsulation layer 830 can be reduced, avoiding the problem of cutting to the third encapsulation layer 830 causing cracks in the third encapsulation layer 830 and extending to the display region 11. The blocking trench 840 divides the third encapsulation layer 830 into a plurality of sections. When a section near the hole region 13 is cut and a crack is generated, an extension path for the crack is blocked by blocking trench 840, thereby avoiding the crack from extending to the display region 11.

For the structural design in this embodiment, it can be applied to other display panels 10, and specifically selected based on the actual situation, which is not limited by the present application.

The present embodiment further provides a display device, including a display panel 10 of any of the above embodiments. Due to the fact that the display device provided in the present embodiment includes the display panel 10 of any of the above embodiments, the display device provided in the present embodiment has the beneficial effects of the display panel 10 of any of the above embodiments, which will not be repeated here.

The display device in the present embodiment includes but is not limited to devices with display functions such as mobile phones, Personal Digital Assistant (Personal Digital Assistant; PDA), tablets, e-books, televisions, access control, smart landline phones, consoles, etc.

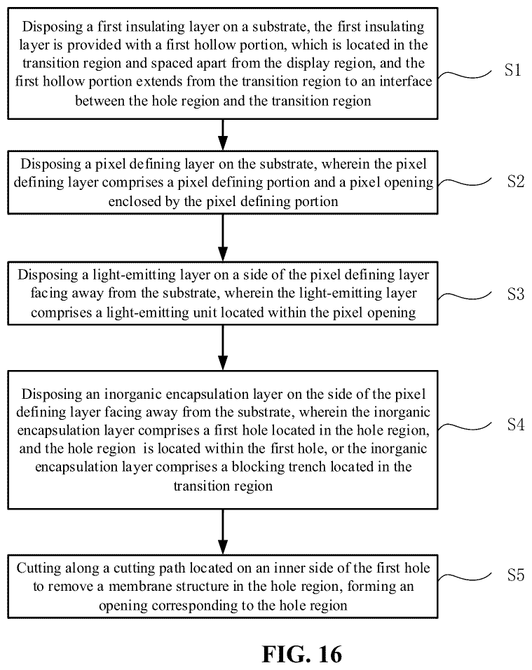

The present embodiments also provide a method for manufacturing a display panel 10, the display panel can be a display panel 10 provided in any of the above embodiments. Referring to FIGS. 1 to 15 and FIG. 16 together. FIG. 16 is a schematic flowchart of a method for manufacturing a display panel according to an embodiment of the present application. The display panel 10 includes a display region 11, a hole region 13, and a transition region 12 located between the display region 11 and the hole region 13. The method comprises:
Step S1: disposing a first insulating layer on a substrate, wherein the first insulating layer is provided with a first hollow portion, the first hollow portion is located in the transition region and spaced apart from the display region, and the first hollow portion extends from the transition region to an interface between the hole region and the transition region.
Step S2: disposing a pixel defining layer on the substrate, wherein the pixel defining layer comprises a pixel defining portion and a pixel opening enclosed by the pixel defining portion.
Step S3: disposing a light-emitting layer on a side of the pixel defining layer facing away from the substrate, wherein the light-emitting layer comprises a light-emitting unit located within the pixel opening.
Step S4: disposing an inorganic encapsulation layer on the side of the pixel defining layer facing away from the substrate, wherein the inorganic encapsulation layer comprises a first hole located in the hole region, and the hole region is within the first hole, or the inorganic encapsulation layer comprises a blocking trench located in the transition region.
Step S5: cutting along a cutting path located on an inner side of the first hole to remove a membrane structure in the hole region, forming an opening corresponding to the hole region.

According to the method of the present embodiment, the first insulating layer 200 is manufactured through step S1. The pixel defining layer 300 is manufactured through step S2. The light-emitting layer 600 is manufactured through step S3. The inorganic encapsulation layer is manufactured through step S4. The hole region 13 is cut through step S5. The pixel defining layer 300 includes a pixel defining portion 310 and a pixel opening 320 enclosed by the pixel defining portion 310. The pixel opening 320 is configured to arrange a light-emitting unit. The first insulating layer 200 located between the pixel defining layer 300 and the substrate 100 is provided with a first hollow portion 210. The first hollow portion 210 is located in the transition region 12 and spaced apart from the display region 11, so that a brittle film layer of the display panel 10 at the first hollow portion 210 is thinned or removed, and when the substrate 100 is cut at the first hollow portion 210, it is difficult for the first insulating layer 200 to form cracks and the cracks are difficult to extend to the display region 11, thereby improving the performance of the OLED display panel 10. The first encapsulation layer 810 encapsulates the first electrode layer 700 and the light-emitting layer 600 to reduce erosion of water and oxygen on the first electrode layer 700 and the light-emitting layer 600. The first section 811 of the first encapsulation layer 810 is located in the display region 11, which improves encapsulation performance of the display panel 10 in the display region 11. A first hole 833 is disposed on the inorganic encapsulation layer to reduce the film thickness of the display panel 10 at the cutting path, in order to reduce the difficulty of cutting the hole region 13. The hole region 13 is within the first hole 833. When cutting the hole region 13, the impact of cutting the hole region 13 on the inorganic encapsulation layer can be reduced, avoiding the problem of cutting to the inorganic encapsulation layer causing cracks in the inorganic encapsulation layer and extending to the display region 11. The blocking trench 840 divides the inorganic encapsulation layer into a plurality of sections. When a section near the hole region 13 is cut to produce a crack, an extension path for the crack is blocked by the blocking trench 840, thereby avoiding the crack from extending to the display region 11.

According to the method of the present embodiment, a first insulating layer 200 is manufactured on the substrate 100 through step S01. The first insulating layer 200 is provided with a first manufacturing trench in the transition region 12, and the first manufacturing trench and the display region 11 are spaced apart. Then, through step S02, a pixel defining layer 300 is manufactured, a pixel opening 320 is enclosed by the pixel defining portion 310, and the pixel opening 320 is configured to arrange a light-emitting unit, achieving the light-emitting display of the display panel 10. Finally, through step S03, the substrate 100 is annularly cut in the first manufacturing trench to form an opening in the hole region 13 of the display panel 10, so as to arrange a photosensitive assembly in the hole region 13, which ensures a photosensitive effect of the photosensitive assembly. Since the film thickness of the display panel 10 is smaller at the first manufacturing trench, when the substrate 100 is cut in the first manufacturing trench, it is difficult for the first insulating layer 200 to form cracks and the cracks are difficult to extend to the display region 11, thereby improving use performance of the OLED display panel 10.

In some optional embodiments, the pixel defining portion 310 includes a first pixel defining portion 311 located in the display region 11 and a second pixel defining portion 312 located in the transition region 12, the second pixel defining portion 312 is annular and spaced apart from the first pixel defining portion 311, and at least part of the second pixel defining portion 312 is arranged in the first manufacturing trench. Prior to step S03, the method further includes:
disposing an isolation structure 500 on a side of the pixel defining layer 300 facing away from the substrate 100, the isolation structure 500 including a first isolation portion 510 located on the first pixel defining portion 311 and two second isolation portions 520 spaced apart and located on the second pixel defining portion 312.

In step S03, the method further includes:
annularly cutting the substrate 100 between the two second isolation portions 520.

In such optional embodiments, the first isolation portion 510 is arranged in the display region 11 and the first isolation opening 511 is enclosed by the first isolation portion 510, so as to partition the light-emitting layer 600 to form first light-emitting units 610 disconnected from each other, thereby reducing crosstalk of carriers in the light-emitting layer 600 and improving display effect of the display panel 10. Moreover, the first light-emitting unit 610 may be manufactured without a precision mask, which can reduce development and use of the precision mask and reduce manufacturing costs. The two second isolation portions 520 are spaced apart on the second pixel defining portion 312, so that when the substrate 100 is cut, the substrate 100 may be annularly cut between the two second isolation portions 520, which reduces a possibility of cutting of the first insulating layer 200. As a result, the first insulating layer 200 is difficult to crack and extend to the display region 11.

In some optional embodiments, the display panel 10 further includes a second light-emitting unit 620 on a side of the second isolation portion 520 facing the hole region 13, and in the step of annularly cutting the substrate 100 in the first manufacturing trench, the method further includes:
annularly cutting the substrate 100 on the second light-emitting unit 620.

In such optional embodiments, the light-emitting layer 600 is disconnected at the second isolation structure 500 to form the second light-emitting unit 620, so that a film layer structure between the two second isolation portions 520 is close to the film structure for cutting in the related art, and when the substrate 100 is cut on the second light-emitting unit 620, the substrate 100 can be cut using an existing cutting device and known device parameters, reducing the difficulty of cutting.

In some optional embodiments, the display panel 10 further includes a second electrode 720 on a side of the second isolation portion 520 facing the hole region 13, and in step S03, the method further includes:
annularly cutting the substrate 100 on the second electrode 720.

In such optional embodiments, the first electrode layer 700 is disconnected at the second isolation structure 500 to form the second electrode 720, so that the film layer structure between the two second isolation portions 520 is close to the film structure for cutting in the related art, and when the substrate 100 is cut on the second electrode 720, the substrate 100 can be cut using an existing cutting device and known device parameters, reducing the difficulty of cutting.

In some optional embodiments, prior to step S03, the method further comprises:
disposing a first encapsulation material layer on the side of the pixel defining layer 300 facing away from the substrate 100, patterning the first encapsulation material layer to obtain a first section 811 located in the display region 11 and a second section 812 located in the transition region 12 and the hole region 13, and at least part of the second section 812 being located in the first hollow portion 210.

In step S03, the method further includes:
annularly cutting the substrate 100 on the second section 812.

In such optional embodiments, the second section 812 of the first encapsulation layer 810 is arranged in the first manufacturing trench, so that a film layer structure in the first manufacturing trench is close to the film structure for cutting in the related art, and the substrate 100 can be cut using an existing cutting device and known device parameters, reducing the difficulty of cutting.

In some optional embodiments, prior to step S03, the method further comprises:
disposing a third encapsulation material layer on the side of the second section 812 facing away from the substrate 100, patterning the third encapsulation material layer to obtain a third section 831 located in the display region 11 and a fourth section 832 located in the transition region 12 and the hole region 13, and at least part of the fourth section 832 being located in the first hollow portion 210.

In step S03, the method further includes:
annularly cutting the substrate 100 on the fourth section 832.

In such optional embodiments, the fourth section 832 of the third encapsulation layer 830 is arranged in the first manufacturing trench, so that the film layer structure in the first manufacturing trench is close to the film structure for cutting in the related art, and the substrate 100 can be cut using an existing cutting device and known device parameters, reducing the difficulty of cutting.

Optionally, before step S03, the method further includes:
removing the second section.

In such optional embodiments, after removing the second section 812, a thickness of the film layer of the transition region 12 is reduced, making it easier to cut, and after removing the second section 812, the problem of cutting causing cracks in the second section 812 to extend towards the display region 11 can be avoided.

Optionally, after disposing the first encapsulation material layer on the side of the pixel defining layer 300 facing away from the substrate 100, the method further comprises:
disposing a second encapsulation material layer on a side of the first encapsulation material layer facing away from the substrate 100;
disposing a third encapsulation material layer on a side of the second encapsulation material layer facing away from the substrate 100, and patterning the third encapsulation material layer to cut at least a portion of the third encapsulation material layer in the transition region 12 and hole region 13 to obtain the third encapsulation layer 830, the third encapsulation layer 830 includes a first hole 833 located in the transition region 12. In such optional embodiments, after the third encapsulation material layer is manufactured, the third encapsulation material layer is cut in the transition region 12 and the hole region 13, so that the third encapsulation material layer in the transition region 12 and the hole region 13 is removed and the second hollow portion 833 is formed. As a result, the brittle film layer of the display panel 10 is thinned at the second hollow portion 833 of the transition region 12 and the hole region 13, and when the substrate 100 is cut at the second hollow portion 833, it is difficult for the third encapsulation layer 830 to form cracks and the cracks are difficult to extend to the display region 11.

What is claimed is:

1. A display panel, comprising a display region, a hole region, and a transition region located between the display region and the hole region, and further comprising:
a substrate;
a pixel defining layer located on a side of the substrate, the pixel defining layer comprising at least one pixel defining portion and a pixel opening enclosed by the pixel defining portion;
a light-emitting layer comprising at least one light-emitting unit located within the pixel opening; and
an inorganic encapsulation layer located on a side of the light-emitting unit facing away from the substrate and comprising a first hole configured to avoid cutting damage, and the hole region being within the first hole.

2. The display panel according to claim 1, wherein the inorganic encapsulation layer comprises a first encapsulation layer and a third encapsulation layer, the third encapsulation layer is located on a side of the first encapsulation layer facing away from the substrate, and the first hole is disposed on the first encapsulation layer or the third encapsulation layer.

3. The display panel according to claim 2, wherein the display panel further comprises:
a second encapsulation layer located between the first encapsulation layer and the third encapsulation layer, the second encapsulation layer comprising an organic material.

4. The display panel according to claim 2, wherein the inorganic encapsulation layer comprises a blocking trench located in the transition region;
the blocking trench is in an annular shape and surrounds the hole region;
the blocking trench is disposed on the first encapsulation layer, and the first hole is disposed on the third encapsulation layer;
the blocking trench extends through the first encapsulation layer along a thickness direction of the display panel; and
the first hole extends through the third encapsulation layer along the thickness direction of the display panel.

5. The display panel according to claim 4, the display panel further comprises:
at least one isolation structure located on the substrate, the isolation structure comprising a first isolation portion located in the display region and a second isolation portion located in the transition region, the second isolation portion spaces apart from the hole region, and the blocking trench is located on a side of the second isolation portion facing away from the substrate.

6. The display panel according to claim 1, further comprising
a first insulating layer located on the substrate, wherein the first insulating layer is provided with a first hollow portion located in the transition region and spaced apart from the display region, and wherein the first hollow portion extends from the transition region to an interface between the hole region and the transition region;
the first hollow portion extends through the first insulating layer along a thickness direction of the display panel; and
the first hollow portion is in an annular shape and surrounds the hole region.

7. The display panel according to claim 6, wherein the first hole is located in the transition region, and
an orthogonal projection of the first hollow portion on the substrate is at least partially overlapped with an orthogonal projection of the first hole on the substrate; or
the orthogonal projection of the first hollow portion on the substrate is within the orthogonal projection of the first hole on the substrate.

8. The display panel according to claim 6, wherein a plurality of third hollow portions located in the transition region are disposed on the first insulation layer, and the plurality of third hollow portions are disposed around the first hollow portion and spaced apart from the first hollow portion;
the plurality of third hollow portions are spaced apart from each other; and
each of the plurality of third hollow portions is in an annular shape and surrounds the hole region.

9. A display panel, comprising a display region, a hole region, and a transition region located between the display region and the hole region, and further comprising:
a substrate;
a pixel defining layer located on a side of the substrate, the pixel defining layer comprising at least one pixel defining portion and a pixel opening enclosed by the pixel defining portion;
a light-emitting layer comprising at least one light-emitting unit located within the pixel opening; and
an inorganic encapsulation layer located on a side of the light-emitting unit facing away from the substrate, and comprising a blocking trench located in the transition region.

10. The display panel according to claim 9, wherein the inorganic encapsulation layer comprises a first encapsulation layer and a third encapsulation layer, the third encapsulation layer is located on a side of the first encapsulation layer facing away from the substrate, and the blocking trench is disposed on the first encapsulation layer or the third encapsulation layer;
the blocking trench is in an annular shape and surrounds the hole region;
the inorganic encapsulation layer comprises a first hole configured to avoid cutting damage and located in the hole region, and the hole region is within the first hole;
the blocking trench is disposed on the first encapsulation layer, and the first hole is disposed on the third encapsulation layer; and
the blocking trench extends through the first encapsulation layer.

11. The display panel according to claim 9, wherein the display panel further comprises:
at least one isolation structure located on the substrate, the isolation structure comprising a second isolation portion located in the transition region, the second isolation portion being spaced apart from the hole region, and the blocking trench being located on a side of the second isolation portion facing away from the substrate.

12. The display panel according to claim 10, wherein the display panel further comprises:
a first insulating layer located on the substrate, the first insulating layer being provided with a first hollow portion, the first hollow portion being located in the transition region and spaced apart from the display region, and the first hollow portion extending from the transition region to an interface between the hole region and the transition region;
wherein the first hollow portion extends through the first insulating layer along a thickness direction of the display panel; and
the first hollow portion is in an annular shape and surrounds the hole region.

13. The display panel according to claim 12, wherein the first hole is located in the transition region, and
an orthogonal projection of the first hollow portion on the substrate is at least partially overlapped with an orthogonal projection of the first hole on the substrate; or
the orthogonal projection of the first hollow portion on the substrate is within the orthogonal projection of the first hole on the substrate.

14. A display panel, comprising a display region, a hole region, and a transition region located between the display region and the hole region, and further comprising:
a substrate;
a first insulating layer located on the substrate, the first insulating layer being provided with a first hollow portion, the first hollow portion being located in the transition region and spaced apart from the display region, and the first hollow portion extending from the transition region to an interface between the hole region and the transition region;
a pixel defining layer located on a side of the first insulating layer facing away from the substrate and comprising a pixel defining portion and a pixel opening enclosed by the pixel defining portion; and
a light-emitting layer comprising at least one light-emitting unit located within the pixel opening.

15. The display panel according to claim 14, wherein the display panel further comprises:
a first encapsulation layer located on a side of the light-emitting unit facing away from the substrate, the first encapsulation layer comprising a first section located in the display region;
a second encapsulation layer located on a side of the first encapsulation layer facing away from the substrate; and
a third encapsulation layer located on a side of the second encapsulation layer facing away from the substrate,
wherein at least one of the first encapsulation layer and the third encapsulation layer is provided with a blocking trench or a first hole for avoiding cutting damage; and
the second encapsulation layer is located in the display region.

16. The display panel according to claim 15, wherein the display panel further comprises:
an isolation structure located on a side of the substrate, the isolation structure comprising a second isolation portion located in the transition region, the second isolation portion being spaced apart from the hole region,
wherein the first encapsulation layer further comprises a second section located in the transition region, the second section is at least partially located within the first hollow portion, the second section is divided by the second isolation portion to form a plurality of sub sections, and a blocking trench is formed between adjacent sub sections of the plurality of sub sections on the isolation structure; and
each sub section of the plurality of sub sections comprises a first thinning portion located on at least one side of the second isolation portion.

17. The display panel according to claim 16, wherein the pixel defining layer comprises a second pixel defining portion located within the first hollow portion, and the second isolation portion is located on a side of the second pixel defining portion facing away from the substrate.

18. The display panel according to claim 17, wherein the isolation structure comprises a first isolation portion located in the display region and a first isolation opening enclosed by the first isolation portion;
the pixel defining layer comprises a first pixel defining portion located in the display region, the pixel opening comprises a first pixel opening enclosed by the first pixel defining portion, and the first pixel opening is in communication with the first isolation opening;
the light-emitting unit comprises a first light-emitting unit located in the first isolation opening;
the display panel further comprises a first electrode layer located on a side of the light-emitting layer facing away from the substrate, and the first electrode layer comprises a first electrode located in the first isolation opening; and
the light-emitting unit comprises a second light-emitting unit located on a side of the second isolation portion facing the hole region.

19. The display panel according to claim 18, wherein the display panel further comprises two or more barrier walls located on a side of the first insulating layer facing away from the substrate, each of the two or more barrier walls is disposed between the first pixel defining portion and the first hollow portion and is annular around the transition region;
the pixel defining portion further comprises an extension portion connected to the first pixel defining portion, the extension portion is at least partially located on a surface of the barrier wall facing away from the substrate;
the extension portion extends to the transition region; and
the extension portion is spaced apart from the first pixel defining portion.

20. The display panel according to claim 15, wherein the third encapsulation layer comprises a first hole configured to avoid cutting damage and located in the hole region, and wherein the first hollow portion extends through the first insulating layer along a thickness direction of the display panel, and
an orthogonal projection of the first hollow portion on the substrate is at least partially overlapped with an orthogonal projection of the first hole on the substrate; or
the orthogonal projection of the first hollow portion on the substrate is within the orthogonal projection of the first hole on the substrate.

21. The display panel according to claim 14, wherein the first hollow portion comprises an upper surface and a lower surface arranged opposite to each other along a thickness direction of the display panel, the upper surface is located on a side of the lower surface facing away from the substrate, the first hollow portion is provided with a first opening located on the upper surface and a second opening located on the lower surface, and an orthographic projection of the second opening on the substrate is within an orthographic projection of the first opening on the substrate;
the first insulating layer is provided with one or more third hollow portions located in the transition region, each of the one or more third hollow portions is disposed around the first hollow portion and spaced apart from the first hollow portion.
